(19) United States
(12) Patent Application Publication
(10) Pub. No.: US 2014/0184226 A1
(43) Pub. Date: Jul. 3, 2014

(54) SYSTEM AND APPARATUS FOR ACTIVE HIGH ORDER SHIMMING

(71) Applicant: GENERAL ELECTRIC COMPANY, Schenectady, NY (US)

(72) Inventor: Derek Allan Seeber, Florence, SC (US)

(73) Assignee: GENERAL ELECTRIC COMPANY, Schenectady, NY (US)

(21) Appl. No.: 13/728,718

(22) Filed: Dec. 27, 2012

(51) Int. Cl. G01R 33/3875; G01R 33/341

(52) U.S. Cl. CPC G01R 33/3875; G01R 33/341
USPC 324/322

(57) ABSTRACT

A gradient coil apparatus for a magnetic resonance imaging (MRI) system includes an inner gradient coil assembly having at least one inner gradient coil and an outer gradient coil assembly disposed around the inner gradient coil assembly and having at least one outer gradient coil. A matrix shim coil is positioned at a radius within the gradient coil apparatus and is configured to provide high order shimming.

### FIELD OF THE INVENTION

The present invention relates generally to a magnetic resonance imaging (MRI) system and in particular to a system and apparatus for active high order shimming.

### BACKGROUND OF THE INVENTION

Magnetic resonance imaging (MRI) is a medical imaging modality that can create pictures of the inside of a human body without using x-rays or other ionizing radiation. MRI uses a powerful magnet to create a strong, uniform, static magnetic field (i.e., the “main magnetic field”). When a human body, or part of a human body, is placed in the main magnetic field, the nuclear spins that are associated with the hydrogen nuclei in tissue water become polarized. This means that the magnetic moments that are associated with these spins become preferentially aligned along the direction of the main magnetic field, resulting in a small net tissue magnetization along that axis (the “z axis,” by convention). An MRI system also comprises components called gradient coils that produce smaller amplitude, spatially varying magnetic fields when a current is applied to them. Typically, gradient coils are designed to produce a magnetic field component that is aligned along the z axis, and that varies linearly in amplitude with position along one of the x, y or z axes. The effect of a gradient coil is to create a small ramp on the magnetic field strength, and concomitantly on the resonant frequency of the nuclear spins, along a single axis. Three gradient coils with orthogonal axes are used to “spatially encode” the MR signal by creating a signature resonance frequency at each location in the body. Radio frequency (RF) coils are used to create pulses of RF energy at or near the resonance frequency of the hydrogen nuclei. The RF coils are used to add energy to the nuclear spin system in a controlled fashion. As the nuclear spins then relax back to their rest energy state, they give up energy in the form of an RF signal. This signal is detected by the MRI system and is transformed into an image using a computer and known reconstruction algorithms.

The gradient coil assembly used in an MRI system may be a shielded gradient coil assembly that consists of inner and outer gradient coil assemblies bonded together with a material such as epoxy resin. Typically, the inner gradient coil assembly incudes inner (or main) coils of X-, Y-, and Z-gradient coil pairs or sets and the outer gradient coil assembly includes the respective outer (or shielding) coils of the X-, Y- and Z-gradient coil pairs or sets. The Z-gradient coils are typically cylindrical with a conductor spirally would around the cylindrical surface. The transverse X- and Y- gradient coils are commonly formed from a copper panel with an insulating backing layer. A conductor turn pattern (e.g., a fingerprint pattern) may be cut in the copper layer of the gradient coil.

MRI systems require a uniform main magnetic field, B₀, in the imaging volume, however, inhomogeneities in the magnetic field may be introduced by various factors such as manufacturing tolerances, environmental effects, design restrictions, imperfections in the magnet, ferromagnetic material near the installation site, and so forth. Inhomogeneities in the magnetic field, B₀, can adversely affect data acquisition and reconstruction of an MR image. For example, magnetic field inhomogeneities may distort position information in the scan volume and degrade the image quality. A process known as “shimming” may be used to compensate for or remove inhomogeneities from the magnetic field, B₀. An MRI magnet may be shimmed using shim or correction coils (active shimming) or passive shims such as pieces of ferromagnetic materials (passive shimming).

Active shimming uses dedicated coils in the magnet to generate a corrective magnetic field. Typically, a current is passed through the shim coils to create the corrective magnetic fields. The current through the shim coils may be adjusted or regulated to provide the appropriate corrective field. Shim coils may be resistive, superconducting or a combination of both. Superconducting shim coils are located inside the magnet and operate in a helium environment. Superconducting shim coils are used to compensate the inhomogeneities (harmonics) caused either by manufacturing tolerances or by the magnetic environment of the scanning room. Typically, the current in the superconducting shim coils is adjusted to a proper value(s) during installation or maintenance of the MRI scanner. Once the current is adjusted to the proper value(s), the current values are fixed and the superconducting coils operate in a persistent mode. To provide static compensation of patient-induced harmonics, which may vary from scan to scan, resistive shim coils (so-called high order shim coils) may be used. The resistive shim coils are often incorporated in the gradient assembly of an MRI scanner and typically include a second order set of shim coils for which the current may be adjusted between scans.

Currently, many MRI systems utilize a wide patient bore which leaves less radial space in the gradient coil system to accommodate high order shim coils. It would be desirable to provide a shim coil design that can be utilized in a small radial space and also allow for second order and higher terms.

### BRIEF DESCRIPTION OF THE INVENTION

In accordance with an embodiment, a gradient coil apparatus for a magnetic resonance imaging (MRI) system includes an inner gradient coil assembly comprising at least one inner gradient coil, an outer gradient coil assembly disposed around the inner gradient coil assembly and comprising at least one outer gradient coil and a matrix shim coil positioned at a radius within the gradient coil apparatus and configured to provide high order shimming.

In accordance with another embodiment, a resonance assembly for a magnetic resonance imaging system includes an RF coil, an RF shield disposed around the RF coil, a gradient coil assembly disposed around the RF shield and including an inner gradient coil assembly, an outer gradient coil assembly disposed around the inner gradient coil assembly, and a matrix shim coil positioned at a radius within the gradient coil apparatus and configured to provide high order shimming, and a superconducting magnet disposed around the gradient coil assembly and including a magnet vessel containing at least one superconducting coil.

### BRIEF DESCRIPTION OF THE DRAWINGS

The invention will become more fully understood from the following detailed description, taken in conjunction with the accompanying drawings, wherein like reference numerals refer to like parts, in which:

FIG. 1 is a schematic block diagram of an exemplary magnetic resonance imaging (MRI) system in accordance with an embodiment;

FIG. 2 is a schematic side elevation view of a resonance assembly in accordance with an embodiment;

FIG. 3 is a diagram of an exemplary matrix shim coil in accordance with an embodiment;

FIG. 4 is a diagram of an exemplary matrix shim coil in accordance with an alternative embodiment;

FIG. 5 is a diagram of a twisted coil for a matrix shim coil in accordance with an embodiment;

FIG. 6 is a diagram of a twisted coil for a matrix shim coil in accordance with an alternative embodiment;

FIG. 7 is a diagram of a matric shim coil using twisted coils in accordance with an embodiment;

FIG. 8 is a diagram of a twisted coil for a matrix shim coil in accordance with an embodiment; and

FIG, 9 is a diagram of a twisted and folded coil for a matrix shim coil in accordance with an embodiment.

### DETAILED DESCRIPTION

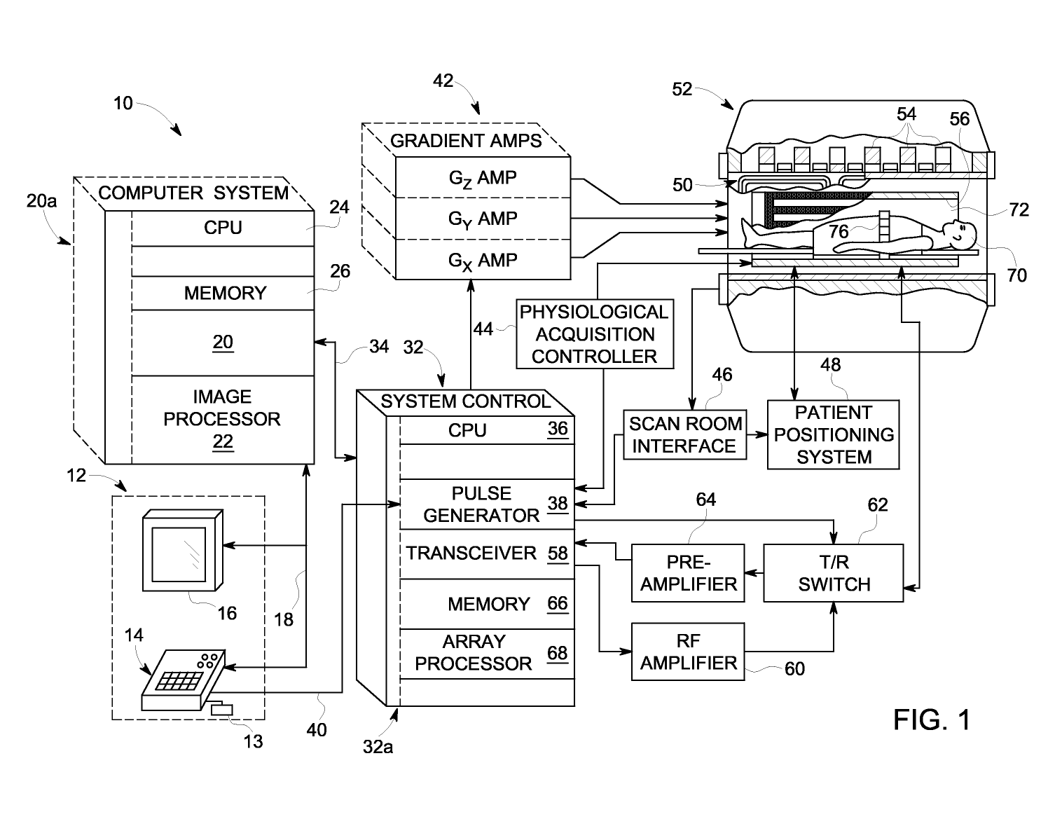

FIG. 1 is a schematic block diagram of an exemplary magnetic resonance imaging (MRI) system in accordance with an embodiment. The operation of MRI system 10 is controlled from an operator console 12 that includes a keyboard or other input device 13, a control panel 14, and a display 16. The console 12 communicates through a link 18 with a computer system 20 and provides an interface for an operator to prescribe MRI scans, display resultant images, perform image processing on the images, and archive data and images. The computer system 20 includes a number of modules that communicate with each other through electrical and/or data connections, for example, such as are provided by using a backplane 20a. Data connections may be direct wired links or may be fiber optic connections or wireless communication links or the like. The modules of the computer system 20 include an image processor module 22, a CPU module 24 and a memory module 26 which may include a frame buffer for storing image data arrays. In an alternative embodiment, the image processor module 22 may be replaced by image processing functionality on the CPU module 24. The computer system 20 is linked to archival media devices, permanent or back-up memory storage or a network. Computer system 20 may also communicate with a separate system control computer 32 through a link 34. The input device 13 can include a mouse, joystick, keyboard, track ball, touch activated screen, light wand, voice control, or any similar or equivalent input device, and may be used for interactive geometry prescription.

The system control computer 32 includes a set of modules in communication with each other via electrical and/or data connections 32a. Data connections 32a may be direct wired links, or may be fiber optic connections or wireless communication links or the like. In alternative embodiments, the modules of computer system 20 and system control computer 32 may be implemented on the same computer system or a plurality of computer systems. The modules of system control computer 32 include a CPU module 36 and a pulse generator module 38 that connects to the operator console 12 through a communications link 40. The pulse generator module 38 may alternatively be integrated into the scanner equipment (e.g., resonance assembly 52). It is through link 40 that the system control computer 32 receives commands from the operator to indicate the scan sequence that is to be performed. The pulse generator module 38 operates the system components that play out (i.e., perform) the desired pulse sequence by sending instructions, commands and/or requests describing the timing, strength and shape of the RF pulses and pulse sequences to be produced and the timing and length of the data acquisition window. The pulse generator module 38 connects to a gradient amplifier system 42 and produces data called gradient waveforms that control the timing and shape of the gradient pulses that are to be used during the scan. The pulse generator module 38 may also receive patient data from a physiological acquisition controller 44 that receives signals from a number of different sensors connected to the patient, such as ECG signals from electrodes attached to the patient. The pulse generator module 38 connects to a scan room interface circuit 46 that receives signals from various sensors associated with the condition of the patient and the magnet system. It is also through the scan room interface circuit 46 that a patient positioning system 48 receives commands to move the patient table to the desired position for the scan.

The gradient waveforms produced by the pulse generator module 38 are applied to gradient amplifier system 42 which is comprised of Gₓ, G_{y} and G_{z} amplifiers. Each gradient amplifier excites a corresponding physical gradient coil in a gradient coil assembly generally designated 50 to produce the magnetic field gradient pulses used for spatially encoding acquired signals. The gradient coil assembly 50 forms part of a resonance assembly 52 that includes a polarizing superconducting magnet with superconducting main coils 54. Resonance assembly 52 may include a whole-body RF coil 56, surface or parallel imaging coils 76 or both. The coils 56, 76 of the RF coil assembly may be configured for both transmitting and receiving or for transmit-only or receive-only. A patient or imaging subject 70 may be positioned within a cylindrical patient imaging volume 72 of the resonance assembly 52. A transceiver module 58 in the system control computer 32 produces pulses that are amplified by an RF amplifier 60 and coupled to the RF coils 56, 76 by a transmit/receive switch 62. The resulting signals emitted by the excited nuclei in the patient may be sensed by the same RF coil 56 and coupled through the transmit/receive switch 62 to a preamplifier 64. Alternatively, the signals emitted by the excited nuclei may be sensed by separate receive coils such as parallel coils or surface coils 76. The amplified MR signals are demodulated, filtered and digitized in the receiver section of the transceiver 58. The transmit/receive switch 62 is controlled by a signal from the pulse generator module 38 to electrically connect the RF amplifier 60 to the RF coil 56 during the transmit mode and to connect the preamplifier 64 to the RF coil 56 during the receive mode. The transmit/receive switch 62 can also enable a separate RF coil (for example, a parallel or surface coil 76) to be used in either the transmit or receive mode.

The MR signals sensed by the RF coil 56 or parallel or surface coil 76 are digitized by the transceiver module 58 and transferred to a memory module 66 in the system control computer 32. Typically, frames of data corresponding to MR signals are stored temporarily in the memory module 66 until they are subsequently transformed to create images. An array processor 68 uses a known transformation method, most commonly a Fourier transform, to create images from the MR signals. These images are communicated through the link 34 to the computer system 20 where it is stored in memory. In response to commands received from the operator console 12, this image data may be archived in long-term storage or it may be further processed by the image processor 22 and conveyed to the operator console 12 and presented on display 16.

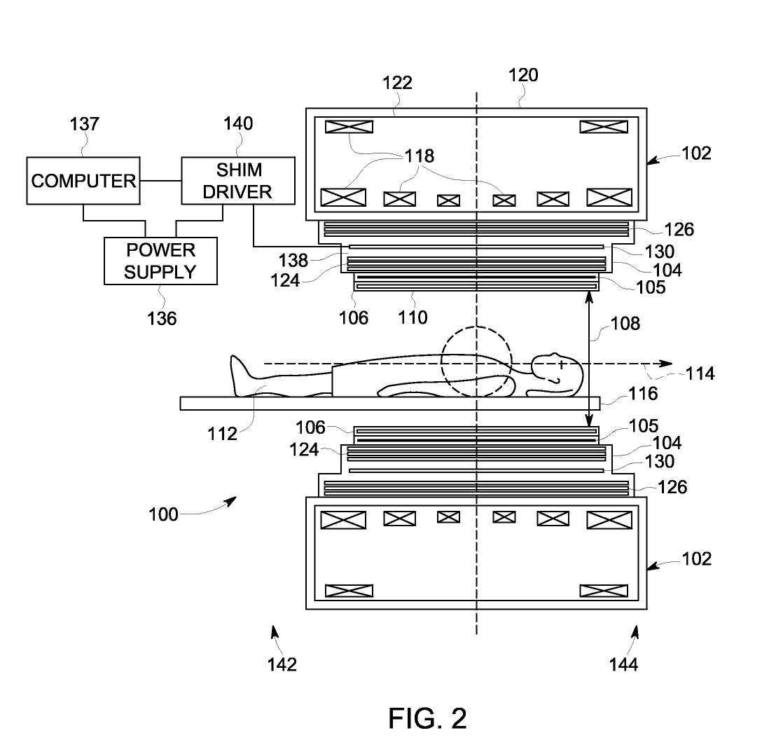

FIG. 2 is a schematic side elevation view of a resonance assembly in accordance with an embodiment. Resonance assembly 100 may be used in an MRI system such as MRI system 10 shown in FIG. 1. The resonance assembly 100 is cylindrical in shape and includes, among other elements, a superconducting magnet 102, a gradient coil assembly 104, an RF shield 105 and a RF coil 106. Various other elements such as covers, supports, suspension members, end caps, brackets, etc. are omitted from FIG. 2 for clarity. A cylindrical patient volume or bore 108 is surrounded by a patient bore tube 110. Patient bore 108 can be configured as a standard bore size (˜60 cm) or as a wide bore size (˜70 cm or greater). RF coil 106 is cylindrical and is disposed around an outer surface of the patient bore tube 110 and mounted inside the cylindrical gradient coil assembly 104. The RF shield 105 is cylindrical in shape and is disposed around the RF coil 106. The gradient coil assembly 104 is disposed around the RF shield 105 and the RF coil 106 in a spaced-apart coaxial relationship and the gradient coil assembly 104 circumferentially surrounds the RF shield 105 and the RF coil 106. Gradient coil assembly 104 is mounted inside magnet 102 and is circumferentially surrounded by magnet 102.

A patient or imaging subject 112 may be inserted into the resonance assembly 100 along a center axis 114 (e.g., a Z-axis) on a patient table or cradle 116. The patient table or cradle 116 is inserted into the resonance assembly at a “patient end” 142 of the resonance assembly and the opposing end of the cylindrical resonance assembly is a “service end” 144. Center axis 114 is aligned along the tube axis of the resonance assembly 100 parallel to the direction of a main magnetic field, BO, generated by the magnet 102. RF coil 106 may be used to apply a radio frequency pulse (or plurality of pulses) to a patient or subject 112 and may be used to receive MR information back from the subject 112 as is well known in the field of MR imaging. RF shield 105 is used to shield the RF coil 106 from external sources of RF radiation. RF shield 105 may be fabricated from any suitable conducting material, for example, sheet copper, circuit boards with conducting copper traces, copper mesh, stainless steel mesh, other conducting mesh, etc. Gradient coil assembly 104 generates time dependent gradient magnetic pulses that are used to spatially encode points in the imaging volume in a known manner.

Superconducting magnet 102 may include, for example, several radially aligned and longitudinally spaced apart superconductive coils 118, each capable of carrying a large current. The superconductive coils 118 are designed to create a magnetic field, BO, within the patient volume 108. The superconductive coils 118 are enclosed in a cryogen environment within a cryogenic envelope 122. The cryogenic environment is designed to maintain the temperature of the superconducting coils 118 below the appropriate critical temperature so that the superconducting coils 118 are in a superconducting state with zero resistance. Cryogenic envelope 122 may include, for example, a helium vessel (not shown) and thermal or cold shields (not shown) for containing and cooling magnet windings in a known manner. Superconducting magnet 102 is enclosed by a magnet vessel 120, e.g., a cryostat vessel. Magnet vessel 120 is configured to maintain a vacuum and to prevent heat from being transferred to the cryogenic envelope 122.

Gradient coil assembly 104 is a self-shielded gradient coil assembly. Gradient coil assembly 104 comprises a cylindrical inner gradient coil assembly or winding 124 and a cylindrical outer gradient coil assembly or winding 126 disposed in a concentric arrangement with respect to a common axis 114. Inner gradient coil assembly 124 includes inner (or main) X-, Y- and Z-gradient coils and outer gradient coil assembly 126 includes the respective outer (or shielding) X-, Y-, and Z-gradient coils. The coils of the gradient coil assembly 104 may be activated by passing an electric current through the coils to generate a gradient field in the patient volume 108 as required in MR imaging. A volume 138 or space between inner gradient coil assembly 124 and outer gradient coil assembly 126 may be filled with a bonding material, e.g., epoxy resin, visco-elastic resin, polyurethane, etc. Alternatively, an epoxy resin with filler material such as glass beads, silica and alumina may be used as the bonding material. It should be understood that magnet and gradient topologies other than the cylindrical assemblies described above with respect to FIGS. 1 and 2 may be used. For example, a flat gradient geometry in a split-open MRI system may also utilize embodiments of the invention as described below.

A high order matrix shim coil 130 is located at a first radius inside the magnet assembly 100. In FIG. 2, the matrix shim coil 130 is located inside the gradient coil assembly 104. For example, the matrix shim coil 130 may be located in a volume or space 138 between the inner gradient coil assembly 124 and the outer gradient coil assembly 126. By placing the matrix shim coil 130 behind the RF shield 105, interactions between the shim coil 130 and the RF coil 106 are limited. In an alternative embodiment, the matrix shim coil 130 may be located at different radial locations within the gradient coil assembly 104 and behind the RF shield 105. The matrix shim coil 130 includes second order or higher unshielded resistive shim coils (not shown). Matrix shim coil 130 is configured to provide compensation of magnetic field inhomogeneities, e.g., patient induced harmonics. Matrix shim coil 130 may be driven by a shim driver 140. Shim driver 140 and matrix shim coil 130 may be powered by a power supply 136, The power supply 136 and shim driver 140 may be operated by a computer system 137 (e.g., computer 20 or systems control computer 42 shown in FIG, 1). Computer 137 and shim driver 140 are configured to control the current supplied to matrix shim coil 130 to provide, for example, global shimming over a desired volume of interest. The matrix shim coil 130 may also be used for dynamic shimming. Waveforms of the shim driver 140 may be controlled by computer 137. In particular, during a scan operation, the resistive coils of the matrix shim coil 130 may be energized to provide dynamic shimming currents to provide real-time compensation of magnetic field distortions. For example, each slice of a MRI sequence may have a unique set of currents to each matrix shim coil 130. The shim driver 140 and computer 137 may also be configured to compensate for eddy currents in the currents to each matrix shim coil.

The matrix shim coil 130 includes a plurality of shim coils disposed on a cylindrical surface around the inner gradient coil assembly 124. The shim coils may be placed or mounted on a cylindrical surface with the appropriate dimensions to be placed inside the gradient coil assembly 104 (e.g., in the volume 138 between the inner gradient coil assembly 124 and the outer gradient coil assembly 126). For example, the coils may be etched on a circuit board or the coils may be fabricated from a continuous length on insulated copper wire wound into the desired pattern. In one embodiment, the circuit board may contain an FR4 backing and etched copper. In another embodiment, the circuit board may be a multi-layer Kapton circuit board with interleaving layers of etched copper and Kapton insulation. Preferably, the matrix shim coil 130 has dimensions that allow placement in small (e.g., <3 mm) radial spaces. The matrix shim coil includes n rows of coils along the z direction and m coils around the circumference of the cylindrical structure to form an n×m array of coils. In another embodiment, the matrix shim coil 130 may include an n×n array of coils.

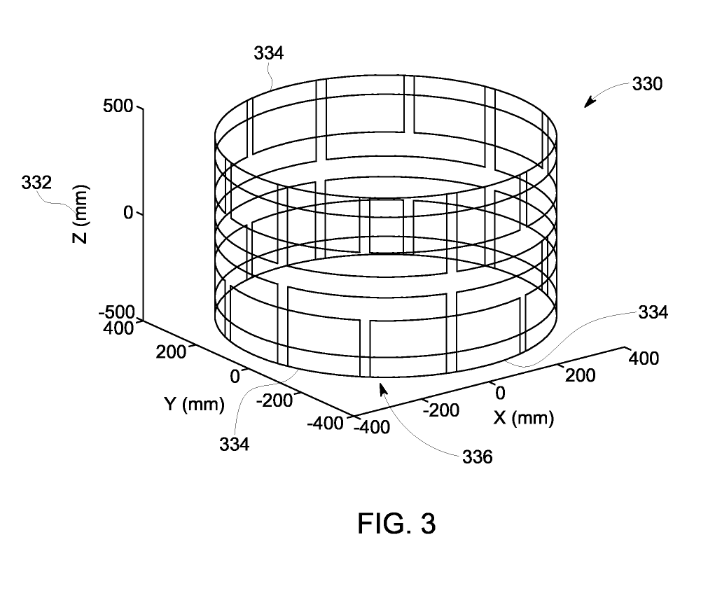

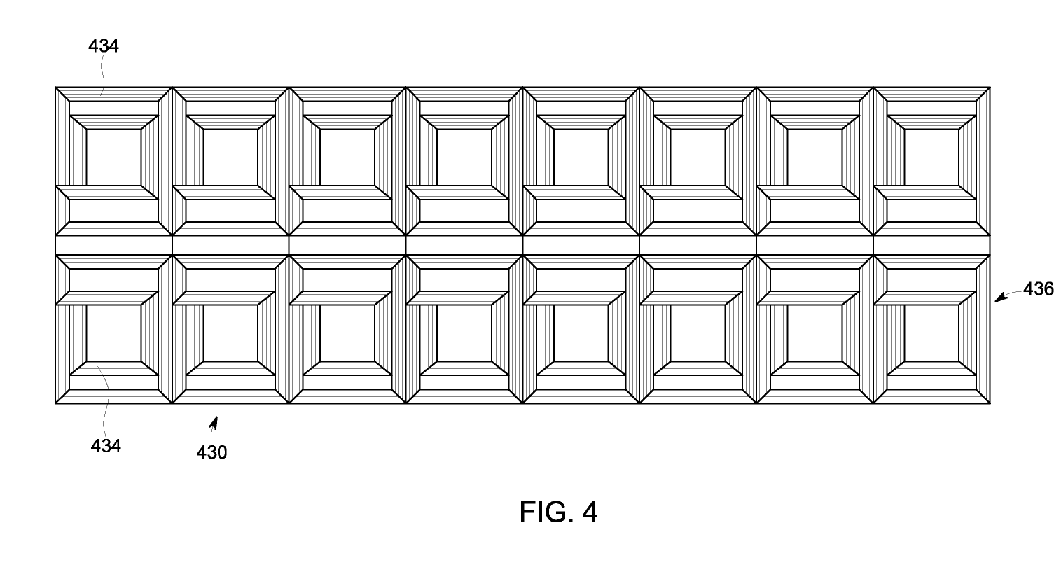

FIG. 3 is a diagram of an exemplary matrix shim coil in accordance with an embodiment. The exemplary matrix shim coil 330 shown in FIG. 3 includes a plurality of shim coils 334 arranged in 4 rows along the z-direction 332 and having six (6) shim coils in each row along the circumference of the cylindrical structure. Matrix shim coil 330 has a total of twenty four (24) shim coils 334. A design of at least a 6×4 matrix or array allows for optimal generation of higher order harmonics. In matric shim coil 330, pairs 336 of rectangular shim coils are positioned in an overlapping manner. The shim coils 334 may also be different shapes, for example, the shim coils 334 may be p-sided polygons (including circles). FIG. 4 is a diagram of an exemplary matrix shim coil in accordance with an alternative embodiment. The matrix shim coil 430 is shown in FIG. 4 unwrapped and flat. The matrix shim coil 430 includes a plurality of square shim coils 434. Pairs 436 of the shim coils 434 are arranged so that the shim coils 434 are concentric with one loop located inside the other.

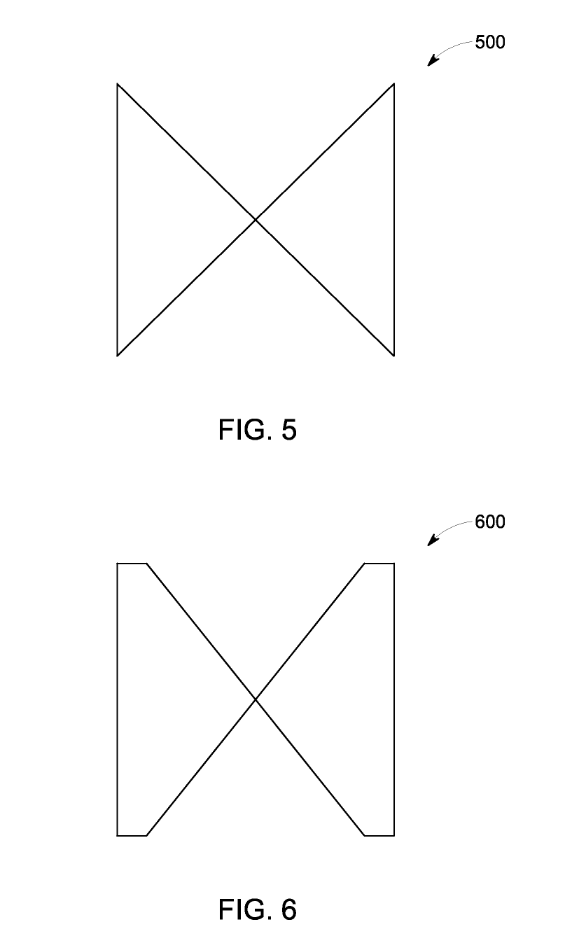

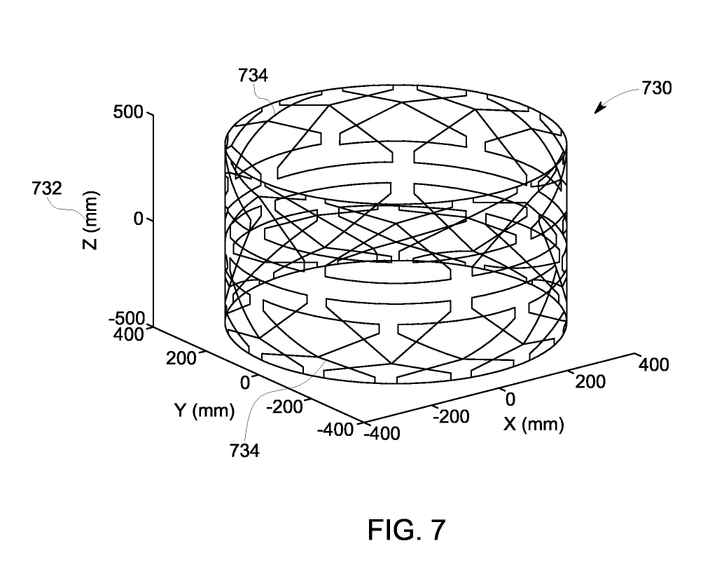

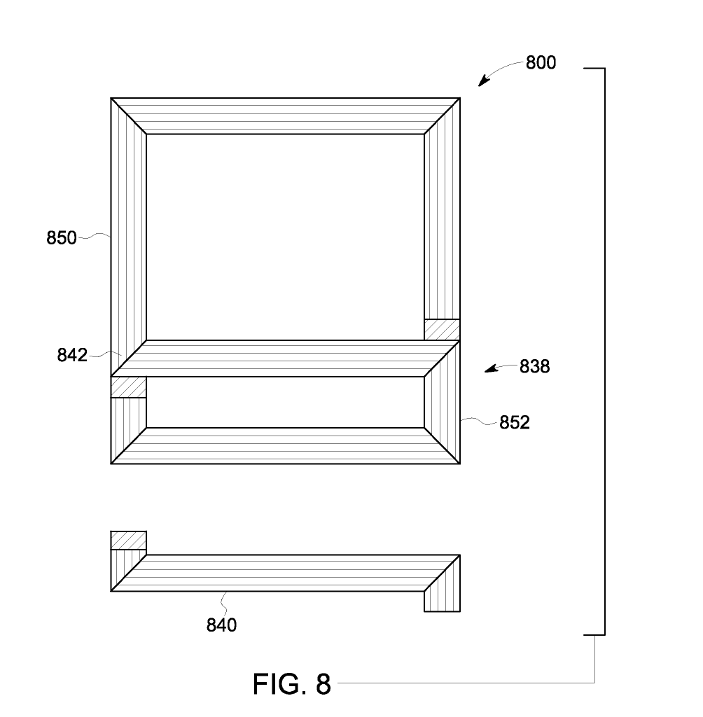

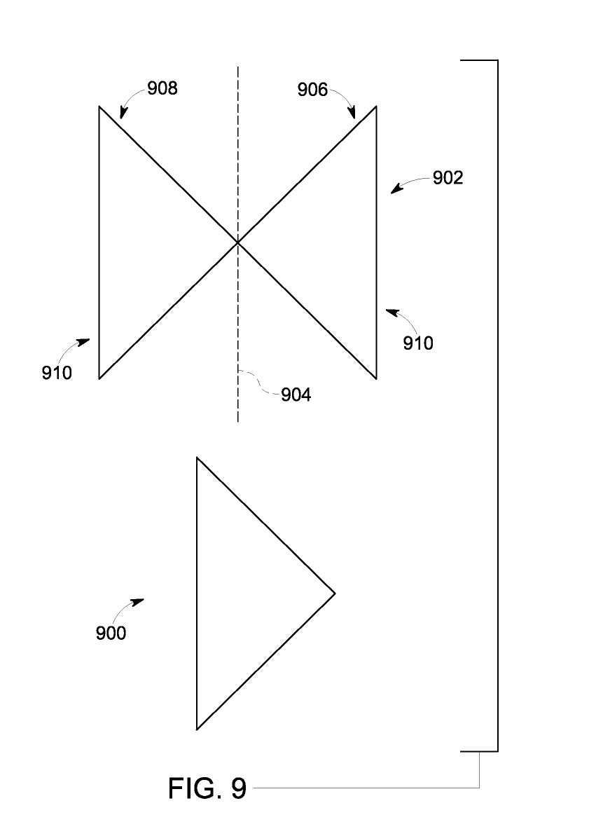

Returning to FIG. 2, polygon (with p-sides) shaped shim coils (including circles) may couple to the gradient coil 104 which can induce large voltages in the matrix shim coil 130 during pulsing and require large voltages in the shim driver 140 to compensate. In order to decouple (or minimize coupling of) the matrix shim coil 130 from the gradient coil 104, the individual shim coils may be twisted into a figure eight or hourglass shape. The figure eight shape is designed to minimize the net radial flux of the gradient coil 104 to reduce feedback voltage to the shim coil driver 140. For example, the positive and negative radial flux from the gradient coil 104 may be canceled to minimize induced voltage in the shim coil driver 140. FIG. 5 is a diagram of a twisted coil for a matrix shim coil in accordance with an embodiment. Shim coil 500 may be created by twisting a rectangular or square coil loop into a figure eight or hourglass shape. The two loops of the figure eight shaped coil 500 may be different shapes. In an embodiment, the figure eight shape may consist of two twisted rectangles resulting in a squared figure eight shape. FIG. 6 is a diagram of a twisted coil a matric shim coil in accordance with an alternative embodiment. In FIG. 6, the two loops of the coil 600 have squared off sides. Alternatively, the two loops could be more rounded or as described further below with respect to FIG. 8, rectangular or square. In addition, in various embodiments, the two loops could be the same size or may be different sizes, ie, an asymmetrical figure eight or hourglass shape. FIG. 7 is a diagram of a matrix shim coil using twisted coils in accordance with an embodiment. The matrix shim coil 730 shown in FIG. 7 includes a plurality of twisted (e.g., figure eight shaped) shim coil 734. As discussed previously, the shim cols 734 are arranged in n rows in the z-direction 732 and with m coils around the circumference. Each shim coil 734 has an asymmetrical figure eight shape. In another embodiment, the loops of the twisted shim coil may have square or rectangular shaped loops as shown in FIG. 8. FIG. 8 is a diagram of a twisted coil for a matric shim coil i accordance with an embodiment. The shim coil 800 is twisted so as to create an area of overlap 838 where a top portion 842 of the coil loop is above a bottom position 840 of the coil loop. For shim coil 800, a first loop 850 of the twisted design is larger than a second loop 852 of the coil 800 (i.e., an asymmetrical coil).

Returning to FIG. 2, in another embodiment, the matrix shim coil 130 may include individual shim coils that are twisted and folded in order to reduce the space used in the z-direction and to increase the efficiency of the matrix shim coil 130. FIG. 9 is a diagram of a twisted and folded coil for a matrix shim coil in accordance with an embodiment. The shim coil 900 (a top view of the folded coil is shown) is created by folding a figure eight shaped coil loop 902 in half over itself. For example, a top portion 906 of the coil is folded over a bottom portion 908 of the coil 900 along an axis 904. In this manner, the straight sides 910 of the loop 902 that generate the Bz field are essentially doubled. This design also allows for an alternative current return path which increases the efficiency of the matrix shim coil. By forming a matrix shim coil using twisted and folded coils 900, the amount of space required in the z-direction by the matrix shim coil is reduced and the matrix shim coil may be compatible with an asymmetric gradient coil where the center of the field of view (FOV) is not at the center of the gradient coil.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims. The order and sequence of any process or method steps may be varied or re-sequenced according to alternative embodiments.

Many other changes and modifications may be made to the present invention without departing from the spirit thereof. The scope of these and other changes will become apparent from the appended claims.

We claim:

1. A gradient coil apparatus for a magnetic resonance imaging (MRI) system, the gradient coil apparatus comprising:
an inner gradient coil assembly comprising at least one inner gradient coil;
an outer gradient coil assembly disposed around the inner gradient coil assembly and comprising at least one outer gradient coil;
a matrix shim coil positioned at a radius within the gradient coil apparatus and configured to provide high order shimming.

2. A gradient coil apparatus according to claim 1, wherein the matrix shim coil is positioned at a radius between the inner gradient coil assembly and the outer gradient coil assembly.

3. A gradient coil apparatus according to claim 1, wherein the plurality of shim coils are arranged in an n x m array.

4. A gradient coil apparatus according to claim 1, wherein the plurality of shim coils are arranged in an n x n array.

5. A gradient coil apparatus according to claim 1, wherein the matrix shim coil is mounted on a cylindrical surface.

6. A gradient coil apparatus according to claim 3, wherein the n rows of the n x m array are disposed along a z-direction.

7. A gradient coil apparatus according to claim 4, wherein the a rows of the n x n array are disposed along a z-direction.

8. A gradient coil apparatus according to claim 1, wherein the matrix shim coil is fabricated on a circuit board.

9. A gradient coil apparatus according to claim 1, wherein the matrix shim coil is fabricated from a continuous length of wire.

10. A gradient coil apparatus according to claim 1, wherein the plurality of shim cols includes at least two overlapping coils.

11. A gradient coil according to claim 1, wherein the plurality of shim coils comprises at least two concentric coils.

12. A gradient coil apparatus according to claim 1, wherein each of the plurality of shim coils has a figure eight shape.

13. A gradient coil apparatus according to claim 12, wherein the figure eight shape is configured to minimize coupling between the matrix shim coil, the inner gradient coil assembly and the outer gradient coil assembly.

14. .A gradient coil apparatus according to claim 1, wherein the matrix shim coil is configured to fit in a radial space less than 3 mm.

15. A resonance assembly for a magnetic resonance imaging system, the resonance assembly comprising:
an RF coil;
an RF shield disposed around the RF coil;
a gradient coil assembly disposed around the RF shield and comprising:
an inner gradient coil assembly;
an outer gradient coil assembly disposed around the inner gradient coil assembly; and
a matrix shim coil positioned at a radius within the gradient coil apparatus and configured to provide high order shimming; and
a superconducting magnet disposed around the gradient coil assembly and comprising a magnet vessel containing at least one superconducting coil.

16. A resonance assembly according to claim 15, wherein the matrix shim coil is positioned at a radius between the inner gradient coil assembly and the outer gradient coil assembly.

17. A resonance assembly according to claim 15, wherein the plurality of shim coils are arranged in an n×m array.

18. A resonance assembly according to claim 15, wherein the plurality of shim coils are arranged in an n×n array

19. A resonance assembly according to claim 15, wherein the matrix shim coil is mounted on a cylindrical surface.

20. A resonance assembly according to claim 15, further comprising a shim coil driver coupled to the matrix shim coil and configured to control the matrix shim coil to provide dynamic shimming.

21. A resonance assembly according to claim 20, wherein the shim coil driver is configured to provide currents to the matrix shim coil that have compensation for eddy currents.

22. A resonance assembly according to claim 15, wherein the matrix shim coil is configured to fit in a radial space less than 3 mm.
